(19) United States
(12) Patent Application Publication
(10) Pub. No.: US 2013/0010442 A1
(43) Pub. Date: Jan. 10, 2013

(54) CIRCUIT ARRANGEMENT AND ASSOCIATED CONTROLLER FOR A MOTOR VEHICLE

(75) Inventors: Michael Heim, Holzgerlingen (DE); Stefan Keil, Kusterdingen (DE); Gerhard Braun, Rottenburg (DE); Georg Voegele, Langenargen (DE)

(73) Assignee: ROBERT BOSCH GMBH, Stuttgart (DE)

(21) Appl. No.: 13/635,093

(22) PCT Filed: Mar. 11, 2011
(86) PCT No.: PCT/EP2011/053735

§ 371 Date: Sep. 14, 2012

(30) Foreign Application Priority Data
Mar. 17, 2010 (DE) 10 2010 002 945.9

(51) Int. Cl. H05K 7/00; H05K 5/06

(52) U.S. Cl. 361/752; 361/748

(57) ABSTRACT

The invention relates to a circuit arrangement comprising an electric and/or electronic circuit unit (10) which has a circuit carrier (14), on which at least one electric and/or electronic component (12) is arranged, and at least one connecting zone comprising a contact unit for electrically contacting the electric and/or electronic circuit unit (10) with other electric and/or electronic components. The invention also relates to a corresponding controller for a motor vehicle. The circuit carrier (14) is designed as at least one lead frame assembly having individual strip conductors (14.11, 14.12), the strip conductors (14.11, 14.12) being arranged in at least two different planes (14.3, 14.4).

### BACKGROUND OF THE INVENTION

The invention relates to a circuit arrangement and to a controller for a motor vehicle comprising such a circuit arrangement.

Controllers for controlling various functions and devices are well known and are used increasingly in the automotive field for controlling various functions of a motor vehicle. Said controllers are available in a wide variety of mechanical embodiments. A controller usually includes a circuit arrangement comprising an electric and/or electronic circuit unit which has a circuit carrier, on which at least one electric and/or electronic component is arranged, and at least one connecting zone comprising a contact unit for electrically contacting the electric and/or electronic circuit unit with other electric and/or electronic components as, for example, actuators, sensors or plugs. The circuit arrangement is disposed as a rule within a housing unit which is sealed off from the surroundings.

In the first publication of the German patent application DE 10 2005 015 717 A1, an electrical circuit arrangement, in particular for a motor vehicle, and an associated controller are described. The electrical circuit arrangement described comprises a circuit carrier having electrical circuit elements and a connecting device serving to electrically connect the circuit carrier. The circuit arrangement is disposed in a housing which is sealed off from the surroundings, said housing having a floor element and a ceiling element. The ceiling element is sealed with respect to the floor element via a circumferential sealing element. In addition, electrical components are disposed in a region of the connecting arrangement lying within the housing. The circuit carrier described is, for example, designed as a ceramic circuit carrier, in particular as a LTCC circuit carrier (LTCC: Low Temperature Cofire Ceramic) and the connecting arrangement described is, for example, designed as a printed circuit board, flexible printed circuit board, flexible film or as a lead frame.

In the American patent publication U.S. Pat. No. 7,514,784 B2, an electronic circuit unit and a corresponding manufacturing method are described. The circuit unit described comprises a circuit carrier, on which electronic components, strip conductors and metal terminals for electrically contacting the circuit carrier are arranged. In this case, the electronic components and the strip conductors are encapsulated by a protective material, and the metal terminals for electrical contacting are arranged outside of the protective material. The metal terminals for connection are arranged on both sides of the circuit carrier, wherein electrical contact can only be applied to the individual metal terminals on one surface.

### SUMMARY OF THE INVENTION

The circuit arrangement according to certain embodiments of the invention has, in contrast, the advantage that the circuit carrier is designed as at least one lead frame assembly having individual strip conductors, the strip conductors being arranged in at least two different planes. The electric and/or electronic circuit unit comprises, for example, a circuit carrier, on which at least one electric and/or electronic component is arranged and at least one connecting zone comprising at least one contact unit for electrically contacting the electric and/or electronic circuit unit with other electric and/or electronic components.

The circuit arrangement according to embodiments of the invention can, for example, be installed in a controller for a motor vehicle, which, for example, is used as a power module for controlling electrical drives of all power classes, such as, e.g., steering drives, hybrid vehicle drives, electric vehicle drives, small motors such as wiper motors, power window actuators, water pumps etc. In addition, usages are conceivable wherever electronic devices have to be protected for further processing operations.

The strip conductors arranged in at least two different planes are, for example, configured such that partial multilayers form a strip conductor crossover and/or a capacitance. In so doing, strip conductor crossovers of the circuit unit required in the layout, which are predefined by the corresponding circuit, can be implemented without the use of additional components, such as wire bondings, bridges etc. Required, discrete capacitor components can be advantageously replaced for reasons of interference suppression or circuit arrangement by means of the capacitances formed. The conventional contacting of the discrete capacitor components by means of soldering assembly is advantageously also thereby no longer required. In contrast to the prior art to date, strip conductor crossovers and/or capacitors are therefore constituted by the three dimensional configuration of the lead frame assembly. The lead frame assembly can, for example, be held by a moldable adhesive film and/or can be encapsulated by a protective material. The partial multilayers of the lead frame assembly or the circuit carrier material which result in this way can now be additionally configured or used as a (plate) capacitor as a result of suitable geometric specifications. Said capacitor can, for example, be used for electrical interference suppression or for the stabilization of an intermediate circuit voltage.

It is particularly advantageous for the housing unit to comprise a protective material which sealingly encapsulates the circuit unit and encapsulates a connecting zone such that the at least one contact unit is embedded in the protective material at least on the lateral surfaces thereof. In a so-called molding process, the open electric and/or electronic circuit unit receives a stable housing configuration by means of the protective material or casting compound or respectively molding compound. Embodiments of the present invention hereby fulfill two essential points, on the one hand the protection of the circuit carrier and the components thereof from external influences, such as, e.g., temperature, dirt and/or water and on the other hand the option of directly contacting the circuit carrier with other electrical components as, for example, a wiring harness. By encapsulating the assembled circuit carrier with the protective material preferably by means of an encapsulation molding operation, a plurality of the otherwise typical production steps can be eliminated, whereby costs can be saved in an advantageous manner. During the encapsulation molding operation, the assembled circuit carrier is directly extrusion-coated or cast with a protective material embodied as plastic, preferably with a thermosetting plastic, whereby the otherwise usual housing components, such as the upper and lower housing, can be eliminated. In this connection, several assembly steps are eliminated during manufacturing, such as, for example, feeding the housing components, screwing the circuit carrier to the lower housing, applying a seal between the upper and lower housing, placing the upper housing onto the lower housing, screwing the two housing components to one another. A stabile connecting zone, which facilitates a direct contacting of the circuit carrier with other electric and/or electronic components having a corresponding mating plug, is particularly a result of the at least lateral embedding of the contact unit into the protective material or casting compound or respectively molding compound. The circuit carrier can thus, for example, be directly connected to a wiring harness via the connecting zone and the associated mating plug. In so doing, the releaseability of the connection between the circuit carrier and the associated mating plug or rather not having to use separate contacting methods such as, for example, the production of welded, soldered or insulation displacement connections etc. is advantageous in this case. Moreover, the use of additional contact units such as, for example, a male multipoint connector can be eliminated. In this way, the manufacturing costs for a circuit arrangement can be advantageously lowered, and a compact, comparatively small circuit arrangement that is well protected from environmental influences results, said circuit arrangement being capable of use in a controller of a motor vehicle.

In an advantageous embodiment of the circuit arrangement according to the invention, the circuit carrier is designed as at least one lead frame assembly having individual strip conductors arranged preferably within the protective material, wherein the at least one contact unit is designed as a contact tongue of the circuit carrier, which is embodied as a lead frame assembly in order to facilitate a direct contacting with other electric and/or electronic components. For this purpose, the corresponding contact units configured as contact tongues are, for example, configured in such a way that they are arranged in a plane or line and the existing interstices are filled with molding compound during the molding process. By means of a multilayered arrangement of the individual strip conductors, it is possible in the simplest way to also dispose the contact tongues in more than one plane. As an alternative, contact tongues of several planes of strip conductors can also be brought into the same plane with respect to each other by bending the lead frame assemblies. The contact tongues provided in a common plane can likewise be arranged laterally offset to one another, for example alternately offset. By means of such embodiments of the contact tongues, the development of a contacting unit to form a multilayered plug connection is facilitated.

In a further advantageous embodiment of the circuit arrangement according to the invention the shape and/or size of the at least one contact unit are adapted to the mechanical and/or electrical requirements, such as, for example, the current carrying capacity. In another advantageous embodiment, the at least one contact unit is designed to be simultaneously contacted on the top and/or bottom side. In so doing, applications having high currents are accommodated in an advantageous manner.

In a further advantageous embodiment of the circuit arrangement according to the invention, the circuit carrier is at least partially arranged on a thermally conductive base plate, which is at least partially encased by the protective material. The thermally conductive base plate is, for example, designed as a metal plate having an insulation layer applied thereto. In order to form a ground connection, the insulation layer can have a recess. The insulation layer can, for example, be applied completely or partially to the thermally conductive base plate by painting, adhesively bonding a film, imprinting, an exposure process or anodizing. Extruded profiles—for example from aluminum—are especially suitable as a thermal base plate. Extruded profiles permit a longitudinally oriented design of a cross-sectional contour, which facilitates a simple and adapted assembly of the circuit arrangement via the extruded profile to an adjacent component or component assembly, for example a cylindrical housing of a drive motor.

By integrating the thermally conductive base plate into the circuit arrangement, an optimal, thermal connection of the circuit carrier or respectively the lead frame assembly and a stable composite with the housing unit including protective material can be achieved in an advantageous manner. In this case, the insulation layer is applied as thinly as possible and can be simultaneously designed as a bonding layer for attaching the circuit carrier or respectively the lead frame assembly. The base plate takes on the function of a heat sink. In addition, the integrated, thermally conductive base plate facilitates a simple continuation of the heating path to a further heat sink. The base plate can thus be connected to the further heat sink by means of, for example, welding, pressing, crimping, adhesive bonding, riveting etc. The circuit arrangement comprising the integrated base plate can, for example, be used in applications in a motor vehicle which require favorable heat dissipation features. Hence, the circuit arrangement can be used, for example, in highly integrated controller assemblies for xenon controllers.

Exemplary embodiments of the invention are depicted in the drawings and are explained in detail in the following description.

### BRIEF DESCRIPTION OF THE DRAWINGS

FIGS. 1 to 3 show in each case a schematic, perspective depiction of a cut-out of a circuit carrier, which is designed as a lead frame assembly, for a circuit arrangement according to the invention.

FIG. 4 shows a schematic, perspective depiction of a first exemplary embodiment of a circuit arrangement according to the invention.

FIG. 5 shows a schematic top view of the first exemplary embodiment of the circuit arrangement according to the invention from FIG. 4, wherein the protective material is transparently depicted for the sake of a better orientation.

FIG. 6 shows a sectional depiction of the first exemplary embodiment of the inventive circuit arrangement along the cutting line VI-VI in FIG. 5 and of a mating plug for contacting the inventive circuit arrangement.

FIG. 7 shows a sectional depiction of the first exemplary embodiment of the inventive circuit arrangement along the cutting line VII-VII in FIG. 5.

FIG. 8 shows a schematic, perspective depiction of a thermally conductive base plate for a circuit arrangement according to the invention.

FIG. 9 shows a schematic, perspective depiction of the thermally conductive base plate from FIG. 8 comprising the assembled circuit carrier, connecting zone and electric and/or electronic components.

FIG. 10 shows a schematic, perspective depiction of a second exemplary embodiment of an inventive circuit arrangement comprising the thermally conductive base plate from FIG. 8.

### DETAILED DESCRIPTION

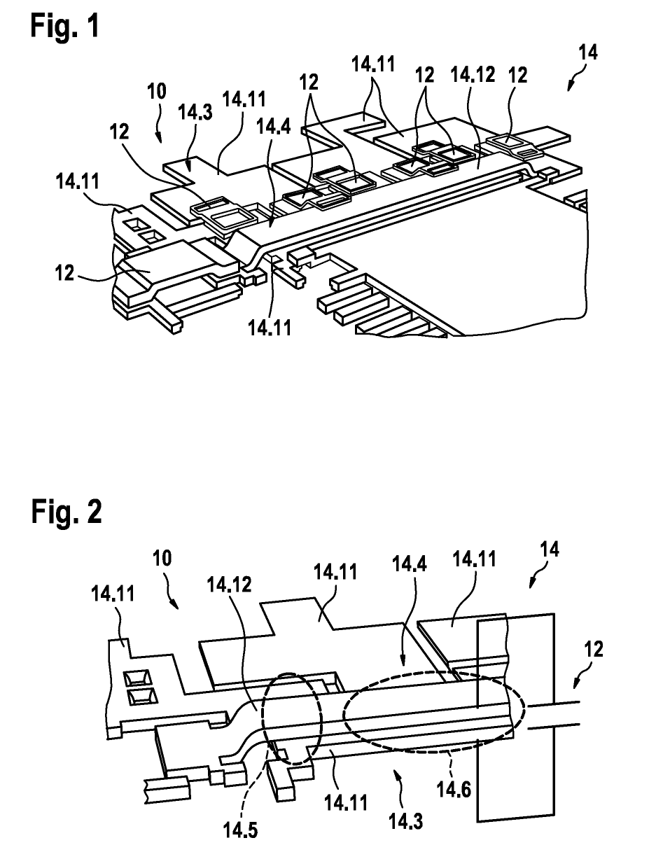

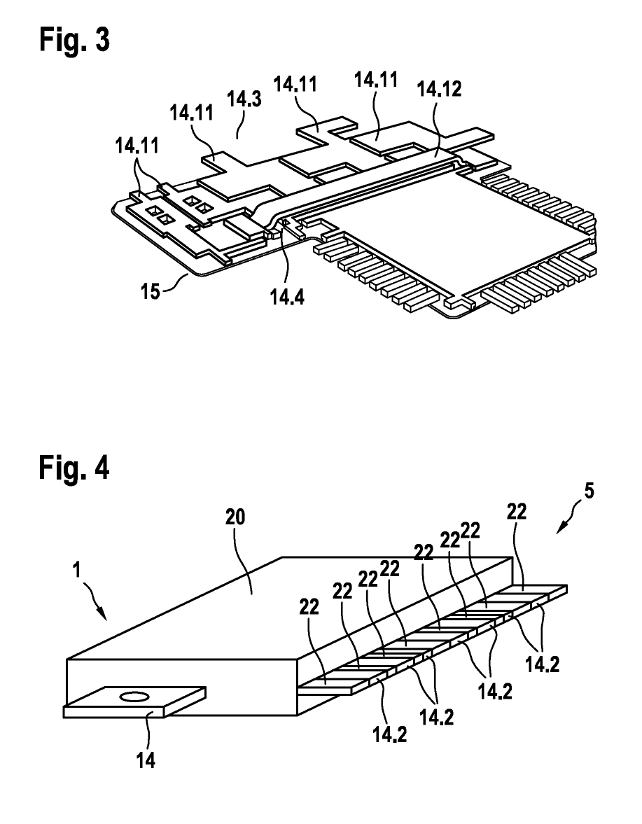

As can be seen in FIGS. 1 to 3, a circuit composite 10 comprises a circuit carrier 14 which is designed according to the invention as at least one lead frame assembly, on which a plurality of electric and/or electronic components are arranged. In addition, the strip conductors 14.11, 14.12 of a circuit carrier 14 designed as a lead frame can be arranged in two different planes 14.3, 14.4. The strip conductors 14.11, 14.12 arranged in at least two differed planes 14.3, 14.4 can, for example, be configured such that partial multilayers form a strip conductor crossover 14.5 and/or a capacitance 14.6. The lead frame assembly 14 can, for example, be held by a moldable adhesive film 15. As a result of forms of embodiment of the invention, Strip conductor crossovers 14.5 required in the layout can be implemented by means of specifications of the corresponding circuit without the use of additional components, such as wire bondings, bridges etc. Required, discrete capacitor components 12 can be advantageously replaced for reasons of interference suppression or circuit design by means of the capacitances formed. In contrast to the prior art to date, strip conductor crossovers and/or capacitors are therefore constituted by the three dimensional configuration of the lead frame assembly 14.

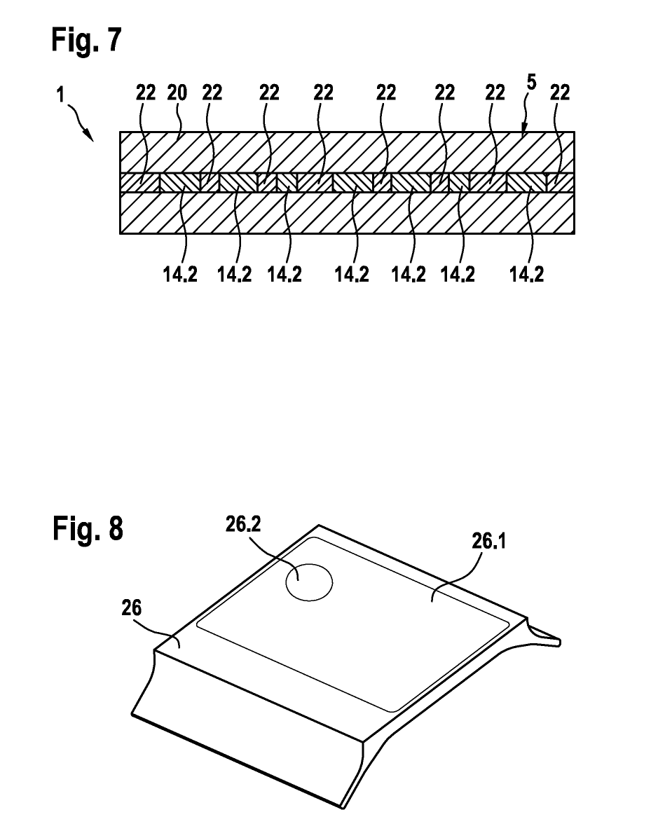

FIGS. 4 to 7 show a first exemplary embodiment of a circuit arrangement 1 according to the invention which comprises an electric and/or electronic circuit unit 10′ having a circuit carrier 14′ configured as a lead frame assembly, on which a plurality of electric and/or electronic components 12 are arranged, and a connecting zone 5 comprising a plurality of contact units 14.2 for electrically contacting the electric and/or electronic circuit unit 10′ with other electric and/or electronic components 30. The circuit unit 10′ is disposed in a housing unit 20 which is sealed off from the surroundings and comprises a protective material that sealingly encapsulates said circuit unit 10′ and encapsulates the connecting zone 5 in such a way that the contact units 14.2 are embedded at least on the lateral surfaces thereof in the protective material 22.

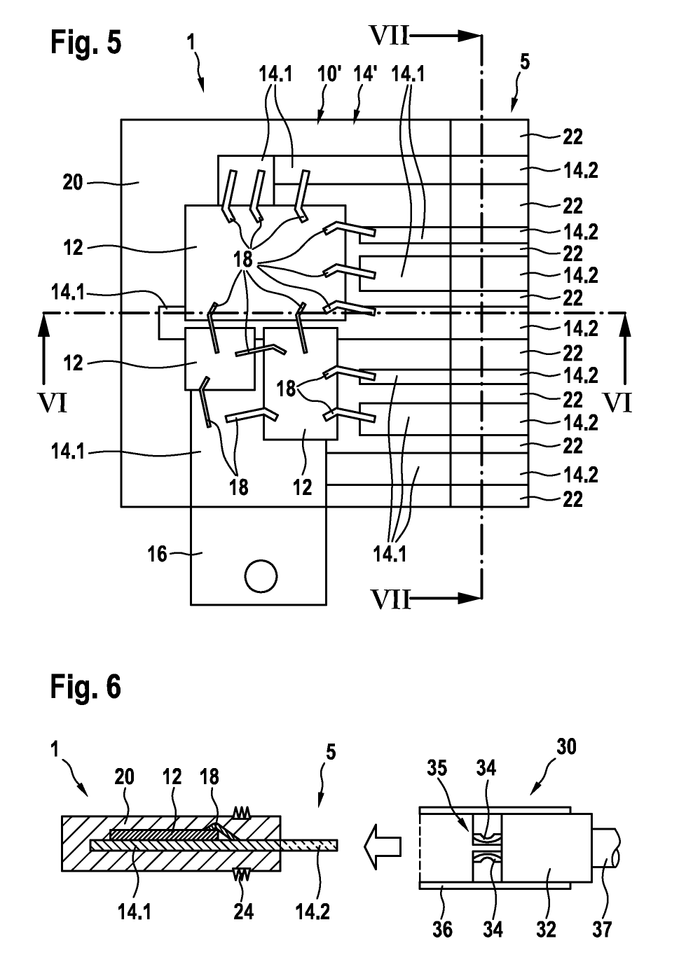

As can be further seen in FIGS. 4 to 7, the individual strip conductors 14.1 of the circuit carrier 14′ designed as a lead frame assembly are arranged within the protective material 20. The contact units 14.2 arranged outside of the protective material 20 are hereby configured as contact tongues of the circuit carrier 14′, which is designed as a lead frame assembly, said contact tongues lying in one plane in order to facilitate a direct contacting with other electric and/or electronic components 30. The width and the thickness of the contact units 14.2 can thus, for example, be designed differently. Likewise the contact units 14.2 can be spaced apart from each other at different distances. The existing interstices 22 between the contact units 14.2 configured as contact tongues are likewise filled with molding compound during the molding process and provide the connecting zone 5 with the required stability and firmness to implement the direct contacting. As can be further seen in FIG. 5 or 6, the electric and/or electronic components 12 can be electrically connected to each other and/or to strip conductors 14.1 of the circuit carrier 14′ designed as a lead frame assembly via connecting elements 18, which, for example, are designed as bond wires. As can be further seen in FIG. 4 or 5, two electric and/or electronic components 12 are arranged on a strip conductor 14.1, which is lead out of the protective material 20 as a cooling element 16 or respectively cooling fin. The cooling element 16 can be connected to a heat sink (not depicted) and/or a ground connection for the purpose of dissipating waste heat.

As can be further seen in FIG. 6, a corresponding contacting device 30 designed as a mating plug for contacting the circuit arrangement 1 with a wiring harness 37 comprises a connecting zone 35 and a contact carrier 32 having externally available resilient contact elements 34, wherein the connecting zone 35 and the contact carrier 32 are arranged inside of a housing 36. For the purpose of contacting, the circuit arrangement 1 including the connecting zone 5 is inserted in the connecting zone 35 of the contacting device 30 until the resilient contact elements 34 come to rest on the surfaces of the contact units 14.2. In the exemplary embodiment depicted, the contact units 14.2 are in each case contacted on the top and bottom side. The shape and/or size of the contact units 14.2 are adapted to the mechanical and/or electrical requirements. A circumferential radial seal 24 seals off the protective material from the corresponding inside surfaces of the housing 36 of the contacting device 30 in order to protect the electrical contacting from environmental influences and/or media as, for example, temperature, dirt and/or water.

As can be seen in FIGS. 8 to 10, a second exemplary embodiment of a circuit arrangement 1′ according to the invention comprises an electric and/or electronic circuit unit 10″ and a thermally conductive base plate designed as a metal plate and having an insulating layer 26.1 applied thereto. The insulating layer 26.1 has a recess 25.2 for forming a ground connection. The electric and/or electronic circuit unit 10″ comprises analogously to the first exemplary embodiment a circuit carrier 14″ designed as a lead frame assembly, on which a plurality of electric and/or electronic components are arranged, and a connecting zone 5′ having a plurality of contact units 14.2′ for electrically contacting the electric and/or electronic circuit unit 10″ with other electric and/or electronic components 30.

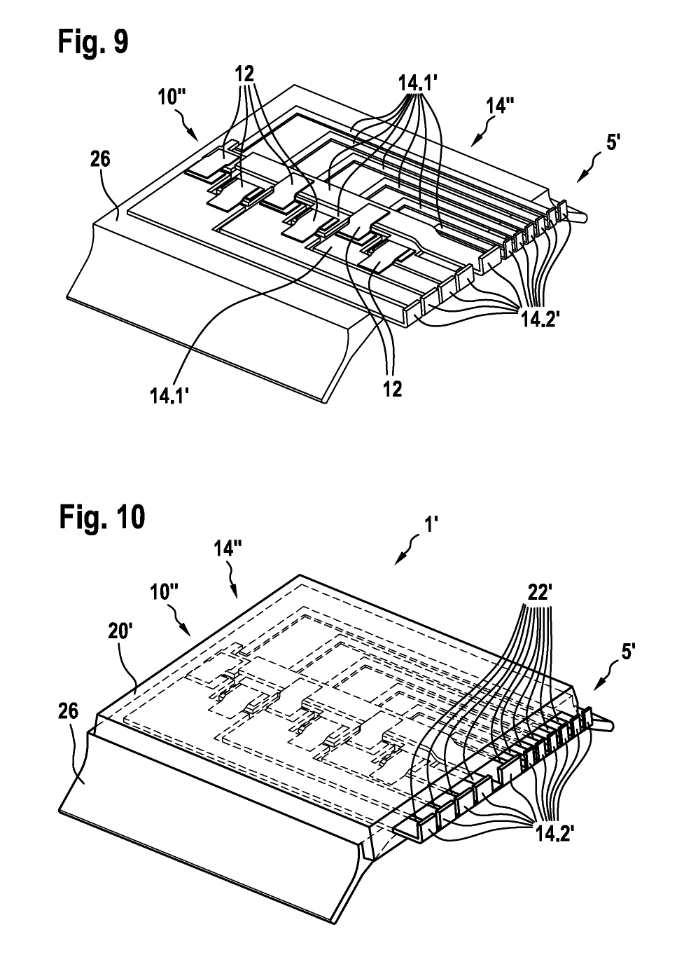

As can be seen in FIG. 9 or 10, the individual strip conductors 14.1′of the circuit carrier 14″ designed as a lead frame assembly are arranged within the protective material 20′ like in the first exemplary embodiment, a plurality of electric and/or electronic components 12 being arranged on said strip conductors. Said strip conductors 14.1′ are connected to the thermally conductive base plate 26 via the insulating layer 26.1, wherein the insulating layer 26.1 can itself be designed as an adhesive. Analogously to the first exemplary embodiment, the contact units 14.2′ arranged outside of the protective material 20′ are likewise configured as contact tongues of the circuit carrier 14′ designed as a lead frame assembly. Said contact tongues lie in the same plane and thereby facilitate a direct contacting with the other electric and/or electronic components 30. The existing interstices 22′ between the contact units 14.2′ designed as contact tongues are likewise filled during the molding process with a molding compound and provide the connecting zone 5′ stability and firmness for implementing the direct contacting.

As can be further seen in FIG. 10, the thermally conductive base plate 26 is not completely encapsulated by the protective material 20′. The integrated, thermally conductive base plate 26 facilitates thereby a simple continuation of the heating path to a heat sink which is not depicted. The base plate 26 can thus, for example, be connected to the heat sink by welding, pressing, crimping, adhesive bonding, riveting etc. In addition, pursuant to an exemplary embodiment which is not depicted, different large electric and/or electronic components or plugs, which should not be encapsulated by the protective material 20′, can be arranged in a region of the thermally conductive base plate 26 which is not encapsulated by said protective material 20′.

By integrating the metal base plate 26 into the circuit arrangement 1′, an optimal thermal connection of the electric and/or electronic components 12 can be achieved via the lead frame assembly 14″. In addition, a stable assembly consisting of circuit unit 10″ and base plate 26 results.

The circuit arrangement according to the invention can, for example, be used in a control unit for a motor vehicle, which, for example, is employed as the power module for controlling electric drives of all performance classes, such as, for example, steering drives, hybrid vehicle drives, electric vehicle drives, small motors as wiper motors, power window actuators, water pumps etc. Moreover, usages are conceivable wherever electronic assemblies have to be protected for further processing operations.

1. A circuit arrangement comprising;
an electric and/or electronic circuit unit which has a circuit carrier, on which at least one electric and/or electronic component is arranged, and at least one connecting zone, the connecting zone including a contact unit for electrically contacting the electric and/or electronic circuit unit with other electric and/or electronic components,
wherein the circuit carrier is designed as at least one lead frame assembly having individual strip conductors, the strip conductors being arranged in at least two different planes.

2. The circuit arrangement according to claim 1, wherein the strip conductors arranged in at least two different planes are configured such that partial multilayers form a strip conductor crossover or a capacitance.

3. The circuit arrangement according to claim 1 wherein the circuit unit is arranged in a housing unit which is sealed off from the surroundings, wherein the housing unit includes a protective material which sealingly encapsulates the circuit unit and encapsulates the at least one connecting zone in such a way that the at least one contact unit is embedded into the protective material at least on the lateral surfaces thereof.

4. The circuit arrangement according to claim 1, wherein the at least one contact unit is configured as a contact tongue of the circuit carrier in order to facilitate a direct contacting with other electric and/or electronic components.

5. The circuit arrangement according to claim 1, wherein the shape and/or size of the at least one contact unit is adapted to the mechanical and/or electrical requirements.

6. The circuit arrangement according to claim 1, wherein the at least one contact unit can be contacted on the top and/or bottom side.

7. The circuit arrangement according to claim 1, wherein the circuit carrier is arranged at least partially on a thermally conductive base plate which is at least partially encapsulated by the protective material.

8. The circuit arrangement according to claim 7, wherein the thermally conductive base plate is embodied as a metal plate having an insulating layer applied thereto.

9. The circuit arrangement according to claim 8, wherein the insulating layer has a recess for forming a ground connection.

10. A controller for a motor vehicle, having a circuit arrangement according to claim 1.
